(19) United States
(12) Patent Application Publication
(10) Pub. No.: US 2018/0375541 A1
(43) Pub. Date: Dec. 27, 2018

(54) USIM EXTENSION CONNECTION DEVICE, AND PORTABLE ELECTRONIC DEVICE PROTECTIVE CASE COMPRISING SAME

(71) Applicant: Samsung Electronics Co., Ltd., Gyeonggi-do (KR)

(72) Inventors: Hyun Seok YOO, Gyeonggi-do (KR); Byung Lyul PARK, Gyeonggi-do (KR)

(21) Appl. No.: 16/061,589

(22) PCT Filed: Jan. 24, 2017
(86) PCT No.: PCT/KR2017/000828

§ 371 Date: Jun. 12, 2018

(30) Foreign Application Priority Data
Jan. 25, 2016 (KR) 10-2016-0008575

(51) Int. Cl. H04B 1/3816; H01R 12/71; H05K 3/36; A45C 11/00

(52) U.S. Cl. CPC H04B 1/3816; H01R 12/716; H05K 2201/058; A45C 11/00; A45C 2011/002; H05K 3/361

(57) ABSTRACT

Disclosed is an electronic device, which is connection device fastenable to a portable electronic device, comprising: a fastening part fastened to a USIM connector of the portable electronic device; a circuit board extending from the fastening part and connected to a plurality of connectors; a processor implemented on the circuit hoard; and a switching circuit unit, wherein the processor is set to supply power to an external device selected, through the switching circuit unit, from among at least one external device connected to the plurality of connectors or to transmit to and receive data from the selected external device. Additionally, various examples identified through the description are possible.

### TECHNICAL FIELD

Embodiments disclosed in the present disclosure relate to a USIM extension connection device and a protective case of a portable electronic device, which includes the same.

### BACKGROUND ART

A portable electronic device may include a universal subscriber identity module (USIM). The USIM, which is formed by combining a subscriber identity module (SIM) card comprising subscriber information and a universal IC card (UICC), may perform various functions such as user authentication, global roaming, e-commerce, or the like.

### DETAILED DESCRIPTION OF THE INVENTION

### Technical Problem

However, in the case of a portable electronic device, such as a smartphone, having a smaller size, the number of slots for mounting the USIM may be limited to one. In addition, even if a plurality of USIM slots are provided in the portable electronic device, an additional USIM slot may be required. In particular, a portable electronic device integrated with a battery may have interfaces insufficient to add a USIM or an external memory (e.g., microSD (Secure Digital)). For example, when an external device (e.g., an external power source) is connected with a USB (Universal Serial Bus) connector disposed in one side (e.g., a bottom end) of the portable electronic device, an interface to be connected with another external device may be insufficient.

### Technical Solution

Embodiments disclosed in the present disclosure may provide a connection device for coupling with a portable electronic device so as to solve the above-described problems and problems occurring in the present disclosure.

According to an embodiment disclosed in the present disclosure, a connection device that is able to couple to a portable electronic device may include a coupling unit coupled to a USIM connector of the portable electronic device, a circuit board extending from the coupling unit and connected with a plurality of connectors, a processor implemented on the circuit board, and a switching circuit unit. The processor may be configured to supply power to an external device selected from at least one external device, which is connected with the plurality of connectors, through the switching circuit unit, or to transceive data with the selected external device.

### Advantageous Effects of the Invention

According to embodiments disclosed in the present disclosure, the connection device for coupling to the portable electronic device is provided, thereby providing the extension interface for connecting with the external device.

In addition, according to embodiments disclosed in the present disclosure, the connection device for coupling with the portable electronic device is seated on the protective case of the portable electronic device, thereby minimizing the size of the structure additionally attached to the portable electronic device.

Besides, a variety of effects directly or indirectly understood through the present disclosure may be provided.

### DESCRIPTION OF THE DRAWINGS

FIG. 1 illustrates a USIM extension connection device, according to an embodiment;

FIG. 2 illustrates the form that the USIM extension connection device is coupled to a portable electronic device, according to an embodiment;

FIG. 3 illustrates a USIM extension connection device applied to a protective case of a portable electronic device, according to an embodiment;

FIG. 4 illustrates another example of a USIM extension connection device applied to a protective case of a portable electronic device, according to an embodiment;

FIG. 5A illustrates a USIM extension connection device applied to a protective case including a display device, according to an embodiment;

FIG. 5B illustrates another example of a USIM extension connection device applied to a protective case including a display device, according to an embodiment;

FIG. 5C illustrates an electronic device coupled to a protective case including a display device, according to an embodiment;

FIG. 6 illustrates an electronic device, according to various embodiments; and

FIG. 7 illustrates a block diagram of the electronic device, according to various embodiments.

### MODE FOR INVENTION

Hereinafter, various embodiments of the present invention may be described with reference to accompanying drawings, but the present invention is not limited to a specific embodiment. Accordingly, those of ordinary skill in the art will recognize that modification, equivalent, and/or alternative on the various embodiments of the present invention can be variously made without departing from the scope and spirit of the present disclosure. With regard to description of drawings, similar components may be marked by similar reference numerals.

In the present disclosure, the expressions “have”, “may have”, “include” and “comprise”, or “may include” and “may comprise” used herein indicate existence of corresponding features (e.g., components such as numeric values, functions, operations, or parts) but do not exclude presence of additional features.

In the present disclosure, the expressions “A or B”, “at least one of A or/and B”, or “one or more of A or/and B”, and the like may include any and all combinations of one or more of the associated listed items. For example, the term “A or B”, “at least one of A and B”, or “at least one of A or B” may refer to all of the case (1) where at least one A is included, the case (2) where at least one B is included, or the case (3) where both of at least one A and at least one B are included.

The terms, such as “first”, “second”, and the like used in the present disclosure may be used to refer to various components regardless of the order and/or the priority and to distinguish the relevant components from other components, but do not limit the components. For example, “a first user device” and “a second user device” indicate different user devices regardless of the order or priority. For example, without departing the scope of the present disclosure, a first component may be referred to as a second component, and similarly, a second component may be referred to as a first component.

It will be understood that when an component (e.g., a first component) is referred to as being “(operatively or communicatively) coupled with/to” or “connected to” another component (e.g., a second component), it may be directly coupled with/to or connected to the other component or an intervening component (e.g., a third component) may be present. In contrast, when an component (e.g., a first component) is referred to as being “directly coupled with/to” or “directly connected to” another component (e.g., a second component), it should be understood that there are no intervening component (e.g., a third component).

According to the situation, the expression “configured to” used in the present disclosure may be used as, for example, the expression “suitable for”, “having the capacity to”, “designed to”, “adapted to”, “made to”, or “capable of”. The term “configured to” must not mean only “specifically designed to” in hardware. Instead, the expression “a device configured to” may mean that the device is “capable of” operating together with another device or other parts. For example, a “processor configured to (or set to) perform A, B, and C” may mean a dedicated processor (e.g., an embedded processor) for performing a corresponding operation or a generic-purpose processor (e.g., a central processing unit (CPU) or an application processor) which performs corresponding operations by executing one or more software programs which are stored in a memory device.

Terms used in the present disclosure are used to describe specified embodiments and are not intended to limit the scope of the present disclosure. The terms of a singular form may include plural forms unless otherwise specified. All the terms used herein, which include technical or scientific terms, may have the same meaning that is generally understood by a person skilled in the art. It will be further understood that terms, which are defined in a dictionary and commonly used, should also be interpreted as is customary in the relevant related art and not in an idealized or overly formal unless expressly so defined in various embodiments of the present disclosure. In some cases, even if terms are terms which are defined in the present disclosure, they may not be interpreted to exclude embodiments of the present disclosure.

An electronic device according to various embodiments of the present disclosure may include at least one of, for example, smartphones, tablet personal computers (PCs), mobile phones, video telephones, electronic book readers, desktop PCs, laptop PCs, netbook computers, workstations, servers, personal digital assistants (PDAs), portable multimedia players (PMPs), Motion Picture Experts Group (MPEG-1 or MPEG-2) Audio Layer 3 (MP3) players, mobile medical devices, cameras, or wearable devices. According to various embodiments, the wearable device may include at least one of an accessory type (e.g., watches, rings, bracelets, anklets, necklaces, glasses, contact lens, or head-mounted-devices (HMDs), a fabric or garment-integrated type (e.g., an electronic apparel), a body-attached type (e.g., a skin pad or tattoos), or a bio-implantable type (e.g., an implantable circuit).

According to various embodiments, the electronic device may be a home appliance. The home appliances may include at least one of, for example, televisions (TVs), digital versatile disc (DVD) players, audios, refrigerators, air conditioners, cleaners, ovens, microwave ovens, washing machines, air cleaners, set-top boxes, home automation control panels, security control panels, TV boxes (e.g., Samsung HomeSync™, Apple TV™, or Google TV™), game consoles (e.g., Xbox™ or PlayStation™), electronic dictionaries, electronic keys, camcorders, electronic picture frames, and the like.

According to another embodiment, an electronic device may include at least one of various medical devices (e.g., various portable medical measurement devices (e.g., a blood glucose monitoring device, a heartbeat measuring device, a blood pressure measuring device, a body temperature measuring device, and the like), a magnetic resonance angiography (MRA), a magnetic resonance imaging (MRI), a computed tomography (CT), scanners, and ultrasonic devices), navigation devices, Global Navigation Satellite System (GNSS), event data recorders (EDRs), flight data recorders (FDRs), vehicle infotainment devices, electronic equipment for vessels (e.g., navigation systems and gyrocompasses), avionics, security devices, head units for vehicles, industrial or home robots, automated teller machines (ATMs), points of sales (POSs) of stores, or internet of things (e.g., light bulbs, various sensors, electric or gas meters, sprinkler devices, fire alarms, thermostats, street lamps, toasters, exercise equipment, hot water tanks, heaters, boilers, and the like).

According to an embodiment, the electronic device may include at least one of parts of furniture or buildings/structures, electronic boards, electronic signature receiving devices, projectors, or various measuring instruments (e.g., water meters, electricity meters, gas meters, or wave meters, and the like). According to various embodiments, the electronic device may be one of the above-described devices or a combination thereof. An electronic device according to an embodiment may be a flexible electronic device. Furthermore, an electronic device according to an embodiment of the present disclosure may not be limited to the above-described electronic devices and may include other electronic devices and new electronic devices according to the development of technologies.

Hereinafter, electronic devices according to various embodiments will be described with reference to the accompanying drawings. In the present disclosure, the term “user” may refer to a person who uses an electronic device or may refer to a device (e.g., an artificial intelligence electronic device) that uses the electronic device.

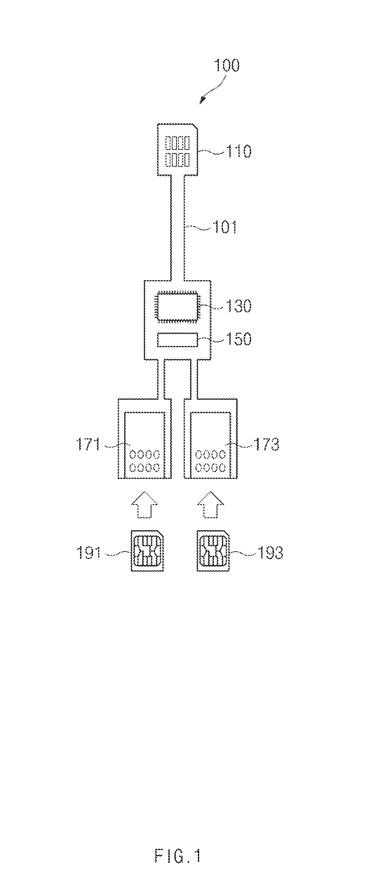

FIG. 1 illustrates a USIM extension connection device, according to an embodiment.

Referring to FIG. 1, a USIM extension connection device 100 may include a coupling unit 110, a processor 130, a switching circuit unit 150, a first connector 171, and a second connector 173. The USIM extension connection device 100 may be totally or partially implemented on a flexible printed circuit board (FPCB) 101. According to one embodiment, the USIM extension connection device 100 may include the FPCB 101 extending from the coupling unit 110 and connected with the first connector 171 and the second connector 173.

The coupling unit 110 may be coupled to a USIM connector of a portable electronic device (e.g., a smartphone). According to one embodiment, the coupling unit 110 may be provided in the form the same as or similar to that of the USIM and thus may be smoothly coupled to the portable electronic device. For example, the coupling unit 110 may have eight connection pins (or terminals), may provide a function the same as or similar to that of an existing USIM through six connection pins, and may provide a power supplying function or a function of transceiving additional data through remaining two connection pins.

The processor 130 may perform various data processing and arithmetic operations associated with the control and/or the communication of at least one of other components of the USIM extension connection device 100. According to one embodiment, the processor 130 may control data transceiving with the portable electronic device when the coupling unit 110 is coupled to the portable electronic device. In addition, the processor 130 may transmit user information, which is stored in a first USIM 191 or a second USIM 193 connected with a first connector 171 or a second connector 173, to the portable electronic device through the switching circuit unit 150. The processor 130 may receive data from the portable electronic device and may store the data in the first USIM 191 or the second USIM 193.

The switching circuit unit 150 may include a switching circuit designed to select the first USIM 191 or the second USIM 193 connected with the first connector 171 or the second connector 173. According to one embodiment, the switching circuit unit 150 may determine whether an external device (e.g., the first USIM 191 or the second USIM 193) is connected with the first connector 171 or the second connector 173, and may perform switching to transceive a signal together with a connector connected with the external device. According to a certain embodiment, when external devices are connected with both the first connector 171 and the second connector 173, the switching circuit unit 150 may perform switching to transceive a signal with at least one connector by the processor 130 by using a value set in the portable electronic device, which is connected with the USIM extension connection device 100, or in a preset reference order

Although the drawing illustrates the switching circuit unit 150 for selecting circuits connected with the first connector 171 and the second connector 173, the present disclosure is not limited thereto. According to various embodiments, the USIM extension connection device 100 may include at least one different connector (e.g., a third connector) other than the first connector 171 and the second connector 173 and may select the at least one connector through the switching circuit unit 150. According to a certain embodiment, one of the first connector 171 or the second connector 173 may be omitted. In this case, the USIM extension connection device 100 may not include the switching circuit unit 150 or may not include the processor 130.

The first connector 171 and the second connector 173 may provide interfaces for coupling to the first USIM 191 and the second USIM 193. The first connector 171 and the second connector 173 may include a body, a connection terminal, and a cover for coupling to the first USIM 191 and the second USIM 193 provided in the forms of cards. The body may be formed with a non-conductor, may be open in one of front and rear portions or both of the front and rear portions, and may have an open port formed in the bottom and extending to a lower portion. The connection terminal may be formed with a conductor and end portions of the connection terminal, which float up and down in the open port of the body, may make contact with the connection pins (or terminals) of the first USIM 191 or the second USIM 193. In addition, the cover may cover the open upper portion of the body. According to one embodiment, the cover may further include an opening such that the first USIM 191 or the second USIM 193 is easily withdrawn from the first connector 171 or the second connector 173. In other words, a user may separate the first USIM 191 or the second USIM 193 from the first connector 171 or the second connector 173 by pushing or withdrawing a portion of the first USIM 191 or the second USIM 193, which is exposed to the outside through the opening formed in the cover, toward any one of the front or the rear of the open body.

In the first connector 171 and the second connector 173, when the first USIM 191 and the second USIM 193 are inserted between the body and the cover, the front ends of the connection terminals lifted upward make contacts with the connection pins of the first USIM 191 and the second USIM 193 to be electrically connected with the connection pins of the first USIM 191 and the second USIM 193.

The first USIM 191 and the second USIM 193, which serve as universal subscriber identity modules, may perform functions of storing the personal information and various data of a user using the portable electronic device. The first USIM 191 and the second USIM 193 may include smart card standard circuits such as UICCs. For example, the first USIM 191 and the second USIM 193 may include a CPU (Central Processing Unit), ROM (Read Only Memory), RAM (Random Access Memory), EEPROM (Eclectically Erasable Programmable ROM), or I/O (Input/Output) circuit. The first USIM 191 and the second USIM 193 may include eight connection pins (or terminals) for transceiving data. In other words, the first USIM 191 and the second USIM 193 may include a power terminal, a reset terminal, a clock terminal, a ground terminal, a single wire protocol (SWP) terminal, an input/output terminal, or extra option terminals (reserved pins).

According to various embodiments, one of the first connector 171 or the second connector 173 included in the USIM extension connection device 100 may provide a different connection interface instead of an interface for the connection with a USIM (e.g., the first USIM 191 or the second USIM 193). According to one embodiment, one of the first connector 171 or the second connector 173 may provide an interface for connection with an external memory (e.g., a secure digital (SD) card or a micro secure digital (micro SD) card), or an interface for connection with an external power source. In this case, a connector for providing an interface to connect with the external memory or the external power source may be formed in the structure different from that of the above-described USIM connector. According to a certain embodiment, the USIM extension connection device 100 may further include another connector other than the first connector 171 and the second connector 173 such that the another connector may provide an interface for connection with the external memory or the external power source.

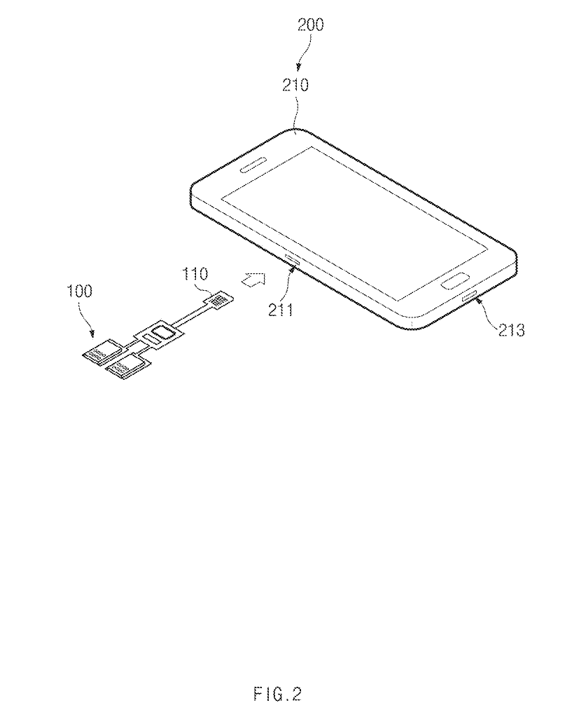

FIG. 2 illustrates the form that the USIM extension connection device is coupled to a portable electronic device, according to an embodiment.

As illustrated in FIG. 2, the USIM extension connection device 100 may be coupled to a USIM connector 211 formed in one surface (or a side surface) of a housing 210 of a portable electronic device 200. According to one embodiment, the portable electronic device 200 may include an opening having a slot form such that a USIM is coupled to one surface of the housing 210. The coupling unit 110 of the USIM extension connection device 100 may be inserted into the opening and electrically connected with the USIM connector 211 formed inside the opening.

As described above, the USIM extension connection device 100 is coupled to the USIM connector 211 formed in one surface of the housing 210 of the portable electronic device 200. Accordingly, even if the portable electronic device 200 has the limited number of USIM slots, the portable electronic device 200 may provide an interface for easy connection with an additional USIM or an external device (e.g., an external memory or an external power source). Especially, in the state that another connector (e.g., a USB connector 213) formed in one surface (a lower end surface) of the housing 210 of the portable electronic device 200 is connected with another external device, an interface for connection with an additionally necessary external device may be provided.

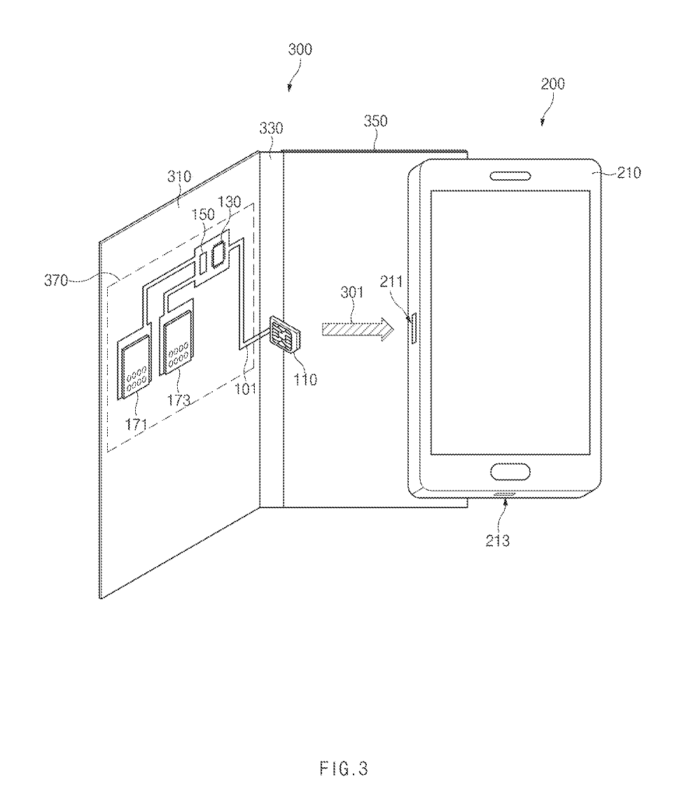

FIG. 3 illustrates a USIM extension connection device applied to a protective case of the portable electronic device, according to an embodiment.

According to various embodiments, the USIM extension connection device 100 may be applied to a protective case 300 of the portable electronic device 200. According to one embodiment, the USIM extension connection device 100 may be detachably assembled with the protective case 300. According to a certain embodiment, the USIM extension connection device 100 may be provided integrally with the protective case 300.

Referring to FIG. 3, the protective case 300 of the portable electronic device 200 may include a front surface part 310, a side surface part 330, and a rear surface part 350 to cover the outer appearance of the portable electronic device 200. The front surface part 310, the side surface part 330, and the rear surface part 350 of the protective case 300 may have sizes equal to or approximate those of a front surface, a side surface, and a rear surface of the portable electronic device 200 to cover the front surface, the side surface, and the rear surface of the portable electronic device 200, respectively. In addition, the protective case 300 may be open/closed in remaining parts except for a part (e.g., the rear surface part 350) fixing and supporting the portable electronic device 200 such that a display and an input device (e.g., a button) formed on at least one surface (e.g., a front surface) of the portable electronic device 200 are used. According to one embodiment, the front surface part 310 of the protective case 300 may perform a hinge action about one side coupled to the side surface part 330 such that the front surface of the portable electronic device 200 is open/closed.

The front surface part 310 of the protective case 300 may include an area 370 on which the USIM extension connection device 100 is seated. According to one embodiment, the area 370, on which the USIM extension connection device 100 is seated, may be formed in a specific area of a surface facing the front surface of the portable electronic device 200 when the front surface part 310 covers the front surface of the portable electronic device 200. However, the present disclosure is not limited thereto. The area 370 on which the USIM extension connection device 100 is seated may be formed on an opposite surface to the surface facing the front surface of the portable electronic device 200. Alternatively, the area 370 on which the USIM extension connection device 100 is seated may be formed such that some components (e.g., the processor 130 or the switching circuit unit 150) of the USIM extension connection device 100 are seated on the surface facing the front surface of the portable electronic device 200 and other components (e.g., the first connector 171 or the second connector 173) of the USIM extension connection device 100 are seated on the opposite surface to the surface facing the front surface of the portable electronic device 200.

According to various embodiments, the area 370, on which the USIM extension connection device 100 is seated, may be recessed by a specific depth allowing the front surface part 310 of the protective case 300 to make close contact with the facing surface when covering the front surface of the portable electronic device 200. In other words, the area 370, on which the USIM extension connection device 100 is seated, may be recessed from one surface of the front surface part 310 facing the front surface of the portable electronic device 200 toward the opposite surface of the front surface part 310. According to one embodiment, the area 370 on which the USIM extension connection device 100 is seated may be formed to be recessed by the heights of the components of the USIM extension connection device 100.

According to various embodiments, an additional cover is applied to the area 370 on which the USIM extension connection device 100 is seated to prevent some components (e.g., a display) formed on the front surface of the portable electronic device 200 from being scratched by a component of the USIM extension connection device 100 when the front surface part 310 of the protective case 300 covers the front surface of the portable electronic device 200.

According to various embodiments, some components of the USIM extension connection device 100 may be formed inside the front surface part 310 of the protective case 300. For example, components (e.g., the processor 130, the switching circuit unit 150, and the FPCB 101) except for the first connector 171 and the second connector 173 may be formed inside the front surface part 310 of the protective case 300.

According to various embodiments, the coupling unit 110 of the USIM extension connection device 100 may be positioned at the side surface part 330 of the protective case 300 to be smoothly coupled to the USIM connector 211, which is formed in the side surface of the portable electronic device 200, through an insertion operation 301. When the USIM extension connection device 100 is provided integrally with the protective case 300, the coupling unit 110 of the USIM extension connection device 100 may protrude from the side surface part 330 of the protective case 300. As described in drawings, the FPCB 101 connecting the coupling unit 110 with other components may be formed inside the front surface part 310 and the side surface part 330 of the protective case 300, and the coupling unit 110 connected with one end of the FPCB 101 may protrude through an opening part formed in the side surface part 330 of the protective case 300. However, the present disclosure is not limited thereto. According to various embodiments, the protruding position of the coupling unit 110 of the USIM extension connection device 100 may be varied depending on the position of the USIM connector 211 of the portable electronic device 200. In other words, when the USIM connector 211 is formed in the front surface or the rear surface of the housing 210 of the portable electronic device 200, the protruding position of the coupling unit 110 of the USIM extension connection device 100 may be formed in the front surface part 310 or the rear surface part 350 of the protective case 300. In this case, other components of the USIM extension connection device 100 may be formed on the front surface part 310 of the protective case 300 and the FPCB 101 may extend to the front surface part 310 or the rear surface part 350 of the protective case 300 to be coupled to the coupling unit 110.

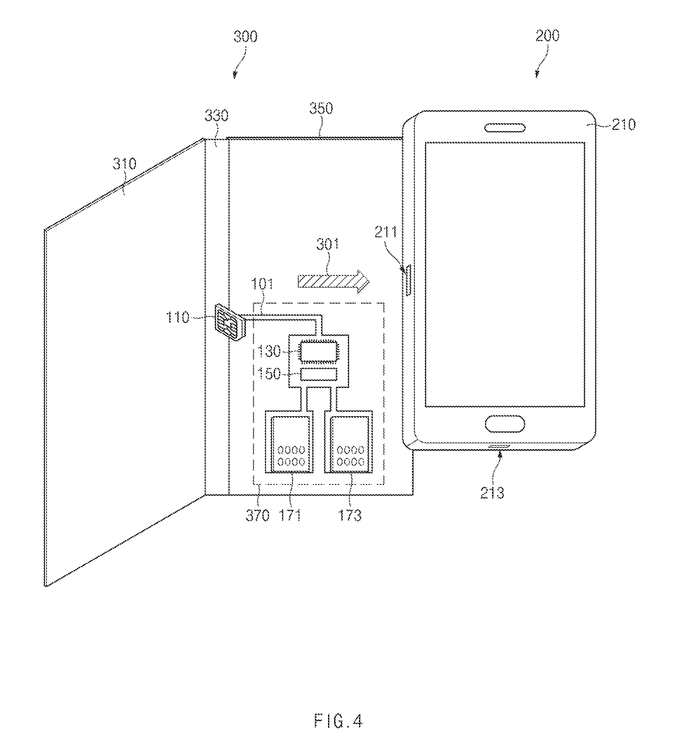

FIG. 4 illustrates another example of the USIM extension connection device applied to the protective case of the portable electronic device, according to an embodiment.

According to various embodiments, the USIM extension connection device 100 may be seated on the rear surface part 350 of the protective case 300. As illustrated in FIG. 4, the rear surface part 350 of the protective case 300 may include the area 370 on which the USIM extension connection device 100 is seated. Similarly, the area 370 on which the USIM extension connection device 100 is seated may be recessed by a specific depth to make close contact with a facing surface when the portable electronic device 200 is coupled to the protective case 300. In addition, an additional cover may be applied to the area 370 to prevent some components formed on the rear surface of the portable electronic device 200 from being scratched.

When the USIM extension connection device 100 is seated on the rear surface part 350 of the protective case 300, although the portable electronic device 200 may be separated from the protective case 300 to use the first connector 171 and the second connector 173, a connection may be prevented from being failed as a motion is frequently made due to a hinge action like the front surface part 310 of the protective case 300, a connection failure may occur.

According to various embodiments, not only may the USIM extension connection device 100 be seated on the front surface part 310 and the side surface part 330 or the rear surface part 350 and the side surface part 330 of the protective case 300, but some components of the USIM extension connection device 100 may be formed on the front surface part 310, the side surface part 330 and the rear surface part 350, respectively. For example, the first connector 171 and the second connector 173, which are more frequently used, may be disposed at the front surface part 310 of the protective case 300, the processor 130 and the switching circuit unit 150, which need not be exposed to the outside, may be disposed inside the rear surface part 350 of the protective case 300, and the coupling unit 110 coupled to the portable electronic device 200 may be formed to protrude from the side surface part 330 of the protective case 300.

According to various embodiments, at least a portion of the front surface part 310, the side surface part 330, or the rear surface part 350 may be omitted from the protective case 300. For example, the protective case 300 may include the front surface part 310 and the side surface part 330 without the rear surface part 350. In this case, the USIM extension connection device 100 may be seated on the front surface part 310 of the protective case 300, and the coupling unit 110 of the USIM extension connection device 100 may be formed to protrude from the side surface part 330 of the protective case 300. In addition, the side surface part 330 of the protective case 300 may be detachably fixed to the side surface of the portable electronic device 200 while the coupling unit 110 of the USIM extension connection device 100 is being inserted into the USIM connector 211 of the portable electronic device 200.

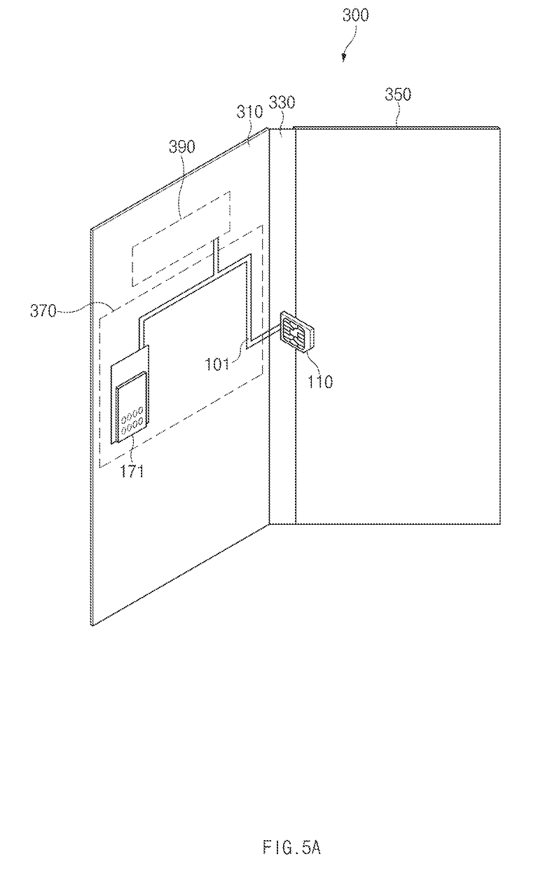

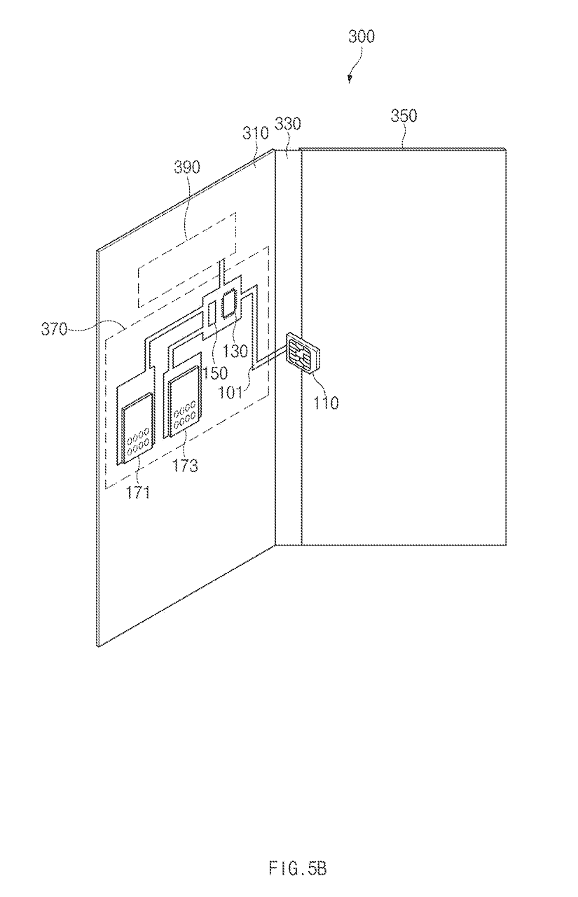

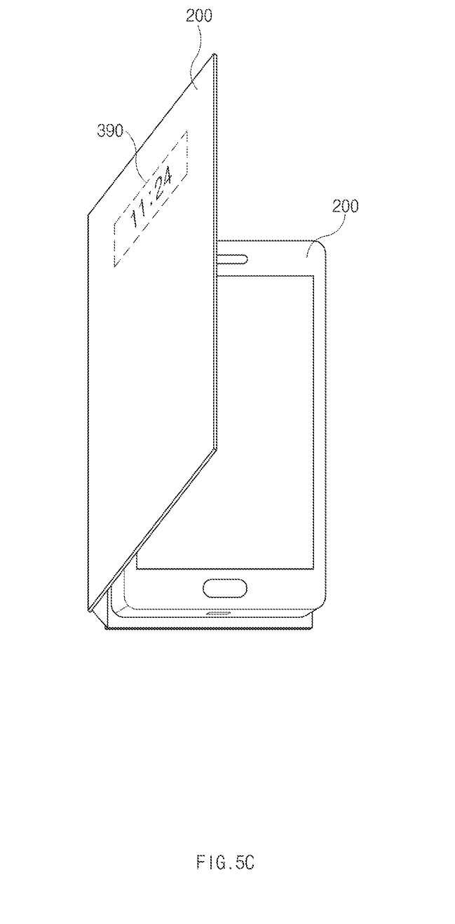

FIG. 5A illustrates the USIM extension connection device applied to a protective case including a display device, according to an embodiment.

Referring to FIG. 5A, the protective case 300 may include a display device 390. According to one embodiment, the display device 390 included in the protective case 300 may include a light-emitting diode (LED). The display device 390 may receive data from the portable electronic device to display various content (e.g., a text, an image, a video, an icon, or a symbol) for a user. The display device 390 may be provided on at least a portion of the front surface part 310, the side surface part 330, or the rear surface part 350 of the protective case 300, and may include a control circuit, which is electrically connected with the portable electronic device to receive data and analyze the received data when the portable electronic device is coupled to the protective case 300, and a display unit which displays various content depending on the analyzed result.

According to various embodiments, when the protective case 300 includes the display device 390, the FPCB 101 of the USIM extension connection device 100 may be connected with the display device 390. When the coupling unit 110 of the USIM extension connection device 100 is connected with the USIM connector of the portable electronic device, the display device 390 may receive data from the portable electronic device. For example, the USIM extension connection device 100 may transceive data associated with a USIM connected with the first connector 171 through six connection pins of eight connection pins of the coupling unit 110 and may bypass data to the display device 390 of the protective case 300 through remaining two connection pins.

As illustrated in drawings, the USIM extension connection device 100 may not include the processor 130 or the switching circuit unit 150 since the USIM extension connection device 100 includes only one connector. However, the present disclosure is not limited thereto. According to various embodiments, the USIM extension connection device 100 may include the processor 130, and the processor 130 may perform a function the same as or similar to that of the control circuit of the display device 390. In addition, although the drawing illustrates that the USIM extension connection device 100 is seated on the front surface part 310 of the protective case 300, some components of the USIM extension connection device 100 may be disposed on at least a portion of the side surface part 330 or the rear surface part 350 of the protective case 300. In this case, the components included in the USIM extension connection device 100 may be connected with the display device 390 through the FPCB 101.

FIG. 5B illustrates another example of the USIM extension connection device applied to the protective case including the display device, according to an embodiment.

According to various embodiments, the USIM extension connection device 100 seated on or provided integrally with the protective case including the display device 390 may include only one connector (e.g., the first connector 171) as illustrated in FIG.

5A. However, as illustrated in FIG. 5B, the USIM extension connection device 100 may include a plurality of connectors (e.g., the first connector 171 and the second connector 173). In this case, the USIM extension connection device 100 includes the processor 130 and the switching circuit unit 150 to select some of a plurality of connectors. According to various embodiments, when the USIM extension connection device 100 includes the processor 130, the display device 390 may be controlled through the processor 130 included in the USIM extension connection device 100.

FIG. 5C illustrates an electronic device coupled to a protective case including a display device, according to an embodiment.

FIG. 5C illustrates that the portable electronic device 200 is coupled to the protective case 300 including the display device 390 illustrated in FIG. 5A or 5B. When the portable electronic device 200 is coupled to the protective case 300 while the coupling unit 110 of the USIM extension connection device 100 protruding from one side of the protective case 300 including the display device 390 is inserted into the USIM connector 211 of the portable electronic device 200, data (e.g., current time data) associated with a function (e.g., a time display function) of the portable electronic device 200 may be output from the portable electronic device 200 to the display device 390.

In drawings, although the display device 390 is provided at the upper portion of the front surface part 310 of the protective case 300 to display the current time, the present disclosure is not limited thereto. According to various embodiments, the display device 390 may be provided on at least a portion of the side surface part 330 or the rear surface part 350 of the protective case 300. The display device 390 may output various notification texts (e.g., a received message, an alarm time, or schedule information) as well as the current time of the portable electronic device 200.

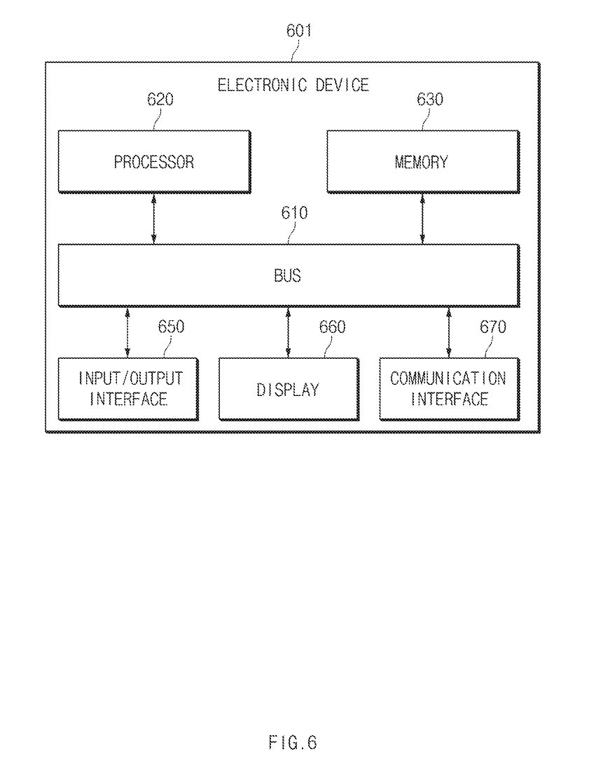

FIG. 6 illustrates an electronic device 601, according to various embodiments. The electronic device 601 illustrated in FIG. 6 may include a component the same as or similar to a component of the portable electronic device 200 coupled to the USIM extension connection device 100 or coupled to the protective case 300, in which the USIM extension connection device 100 is seated, or provided integrally with the USIM extension connection device 100.

Referring to FIG. 6, according to various embodiments, an electronic device 601, a first electronic device 602, a second electronic device 604, or a server 606 may be connected each other over a network 662 or a short range communication 664. The electronic device 601 may include a bus 610, a processor 620, a memory 630, an input/output interface 650, a display 660, and a communication interface 670. According to an embodiment, the electronic device 601 may not include at least one of the above-described components or may further include other component(s).

For example, the bus 610 may interconnect the above-described components 610 to 670 and may include a circuit for conveying communications (e.g., a control message and/or data) among the above-described components.

The processor 620 may include one or more of a central processing unit (CPU), an application processor (AP), or a communication processor (CP). The processor 620 may perform various data processing and arithmetic operations associated with the control and/or the communication of at least one of other components of the electronic device 601. According to an embodiment, the processor 620 may control the transmission of data related to the function of the electronic device 601 to the USIM extension connection device 100 or may control the reception of the user information from the USIM extension connection device 100.

The memory 630 may include a volatile and/or nonvolatile memory. For example, the memory 630 may store commands or data associated with at least one other component(s) of the electronic device 601.

The input/output interface 650 may play a role, for example, of an interface which transmits a command or data input from a user or another external device, to other component(s) of the electronic device 601. Furthermore, the input/output interface 650 may output a command or data, received from other component(s) of the electronic device 601, to a user or another external device.

The display 660 may include, for example, a liquid crystal display (LCD), a light-emitting diode (LED) display, an organic LED (OLED) display, a microelectromechanical systems (MEMS) display, or an electronic paper display. The display 660 may display, for example, various contents (e.g., a text, an image, a video, an icon, a symbol, and the like) to a user. The display 660 may include a touch screen and may receive, for example, a touch, gesture, proximity, or hovering input using an electronic pen or a part of a user's body.

The communication interface 670 may establish communication between the electronic device 601 and an external device. According to one embodiment, the communication interface may establish communication between the USIM extension connection device 100 and the portable electronic device 200 connected with the USIM extension connection device 100.

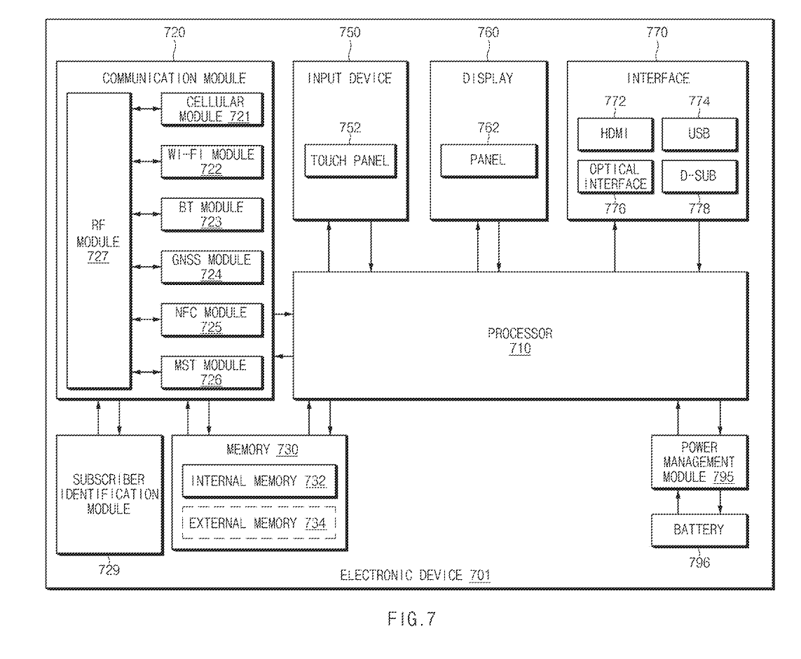

FIG. 7 illustrates a block diagram 700 of an electronic device 701, according to various embodiments.

Referring to FIG. 7, an electronic device 701 may include, for example, all or a part of the electronic device 601 illustrated in FIG. 6. The electronic device 701 may include one or more processors (e.g., an application processor (AP)) 710, a communication module 720, a subscriber identification module 729, a memory 730, an input device 750, a display 760, an interface 770, a power management module 795, and a battery 796.

The processor 710 may drive, for example, an operating system (OS) or an application to control a plurality of hardware or software components connected to the processor 710 and may process and compute a variety of data. For example, the processor 710 may be implemented with a System on Chip (SoC). According to an embodiment, the processor 710 may further include a graphic processing unit (GPU) and/or an image signal processor. The processor 710 may include at least a part (e.g., a cellular module 721) of components illustrated in FIG. 7. The processor 710 may load a command or data, which is received from at least one of other components (e.g., a nonvolatile memory), into a volatile memory and process the loaded command or data. The processor 710 may store a variety of data in the nonvolatile memory.

The communication module 720 may be configured the same as or similar to the communication interface 670 of FIG. 6. The communication module 720 may include the cellular module 721, a Wi-Fi module 722, a Bluetooth (BT) module 723, a GNSS module 724 (e.g., a GPS module, a Glonass module, a Beidou module, or a Galileo module), a near field communication (NFC) module 725, a MST (Magnetic Secure Transmission) module 726 and a radio frequency (RF) module 727.

The cellular module 721 may provide, for example, voice communication, video communication, a character service, an Internet service, or the like over a communication network. According to an embodiment, the cellular module 721 may perform discrimination and authentication of the electronic device 701 within a communication network by using the subscriber identification module (e.g., a SIM card) 729. According to an embodiment, the cellular module 721 may perform at least a portion of functions that the processor 710 provides. According to an embodiment, the cellular module 721 may include a communication processor (CP).

Each of the Wi-Fi module 722, the BT module 723, the GNSS module 724, the NFC module 725, or the MST module 726 may include a processor for processing data exchanged through a corresponding module, for example. According to an embodiment, at least a part (e.g., two or more) of the cellular module 721, the Wi-Fi module 722, the BT module 723, the GNSS module 724, the NFC module 725, or the MST module 726 may be included within one Integrated Circuit (IC) or an IC package.

For example, the RF module 727 may transmit and receive a communication signal (e.g., an RF signal). For example, the RF module 727 may include a transceiver, a power amplifier module (PAM), a frequency filter, a low noise amplifier (LNA), an antenna, or the like. According to another embodiment, at least one of the cellular module 721, the Wi-Fi module 722, the BT module 723, the GNSS module 724, the NFC module 725, or the MST module 726 may transmit and receive an RF signal through a separate RF module.

The subscriber identification module 729 may include, for example, a card and/or embedded SIM that includes a subscriber identification module and may include unique identify information (e.g., integrated circuit card identifier (ICCID)) or subscriber information (e.g., integrated mobile subscriber identity (MI)). The subscriber identification module 729 may include an USIM (e.g., the first USIM 191 or the second USIM 193) connected to a connector (e.g., the first connector 171 or the second connector 173) of the USIM extension connection device 100.

The memory 730 (e.g., the memory 630) may include an internal memory 732 or an external memory 734. For example, the internal memory 732 may include at least one of a volatile memory (e.g., a dynamic random access memory (DRAM), a static RAM (SRAM), a synchronous DRAM (SDRAM), or the like), a nonvolatile memory (e.g., a one-time programmable read only memory (OTPROM), a programmable ROM (PROM), an erasable and programmable ROM (EPROM), an electrically erasable and programmable ROM (EEPROM), a mask ROM, a flash ROM, a flash memory (e.g., a NAND flash memory or a NOR flash memory), or the like), a hard drive, or a solid state drive (SSD).

The external memory 734 may further include a flash drive such as compact flash (CF), secure digital (SD), micro secure digital (Micro-SD), mini secure digital (Mini-SD), extreme digital (xD), a multimedia card (MMC), a memory stick, or the like. The external memory 734 may be operatively and/or physically connected to the electronic device 701 through various interfaces. According to an embodiment, the external memory 734 may be connected to the electronic device 701 through the connector (e.g., the first connector 171 or the second connector 173) of the USIM extension connection device 100.

The input device 750 may include, for example, a touch panel 752. For example, the touch panel 752 may use at least one of capacitive, resistive, infrared and ultrasonic detecting methods. Also, the touch panel 752 may further include a control circuit. The touch panel 752 may further include a tactile layer to provide a tactile reaction to a user.

The display 760 (e.g., the display 660) may include a panel 762. The panel 762 may be the same as or similar to the display 660 illustrated in FIG. 6. The panel 762 may be implemented, for example, to be flexible, transparent or wearable. The panel 762 and the touch panel 752 may be integrated into a single module. According to an embodiment, the display 760 may further include a control circuit for controlling the panel 762.

The interface 770 may include, for example, a high-definition multimedia interface (HDMI) 772, a universal serial bus (USB) 774, an optical interface 776, or a D-subminiature (D-sub) 778. The interface 770 may be included, for example, in the communication interface 670 illustrated in FIG. 6. Additionally or alternatively, the interface 770 may include, for example, a mobile high definition link (MHL) interface, a SD card/multi-media card (MMC) interface, or an infrared data association (IrDA) standard interface.

The power management module 795 may manage, for example, power of the electronic device 701. According to an embodiment, a power management integrated circuit (PMIC), a charger IC, or a battery or fuel gauge may be included in the power management module 795. The PMIC may have a wired charging method and/or a wireless charging method. The wireless charging method may include, for example, a magnetic resonance method, a magnetic induction method or an electromagnetic method and may further include an additional circuit, for example, a coil loop, a resonant circuit, or a rectifier, and the like. The battery gauge may measure, for example, a remaining capacity of the battery 796 and a voltage, current or temperature thereof while the battery is charged. The battery 796 may include, for example, a rechargeable battery and/or a solar battery.

Each of the above-mentioned components of the electronic device according to various embodiments of the present disclosure may be configured with one or more parts, and the names of the components may be changed according to the type of the electronic device. In various embodiments, the electronic device may include at least one of the above-mentioned components, and some components may be omitted or other additional components may be added. Furthermore, some of the components of the electronic device according to various embodiments may be combined with each other so as to form one entity, so that the functions of the components may be performed in the same manner as before the combination.

As described above, according to various embodiments, a connection device (e.g., the USIM extension connection device 100) that is able to couple to a portable electronic device (e.g., the portable electronic device 200) may include a coupling unit (e.g., the coupling unit 110) coupled to a universal subscriber identity module (USIM) connector (e.g., the USIM connector 211) of the portable electronic device, a circuit board (e.g., the FPCB 101) extending from the coupling unit and connected with a plurality of connectors (e.g., the first connector 171 and the second connector 173), a processor (e.g., the processor 130) implemented on the circuit board, and a switching circuit (e.g., the switching circuit unit 150). The processor may be configured to supply power to an external device selected from at least one external device (e.g., the first USIM 191 or the second USIM 193), which is connected with the plurality of connectors, through the switching circuit unit, or to transceive data with the selected external device.

According to various embodiments, the circuit board may include an FPCB.

According to various embodiments, the plurality of connectors may include at least one of a USIM connector, an external memory connector, or an external power source connector.

According to various embodiments, a protective case (e.g., the protective case 300) of a portable electronic device (e.g., the portable electronic device 200), a connection device (e.g., the USIM extension connection device 100) being able to couple to the portable electronic device and being detachable from the protective case, may include a front surface part (e.g., a front surface part 310) formed to cover a front surface of the portable electronic device, a side surface part (e.g., the side surface part 330) formed to cover a side surface of the portable electronic device, and a rear surface part (e.g., the rear surface part 350) formed to cover a rear surface of the portable electronic device. A coupling unit (e.g., the coupling unit 110) of the connection device coupled to a universal subscriber identity module (USIM) connector (e.g., the USIM connector 211) of the portable electronic device may be positioned at the side surface part. A circuit board (e.g., the FPCB 101) extending from the coupling unit and connected with a plurality of connectors (e.g., the first connector 171 and the second connector 173) of the connection device, a processor (e.g., the processor 130) implemented on the circuit board, a switching circuit unit (e.g., the switching circuit unit 150) implemented on the circuit board, and the plurality of connectors may be seated on at least a portion of the front surface part or the rear surface part.

According to various embodiments, at least a portion of the circuit board, the processor, or the switching circuit part of the connection device may be disposed inside at least a portion of the front surface part or the rear surface part.

According to various embodiments, when the circuit board is disposed inside the at least a portion of the front surface part or the rear surface part, one end of the circuit board connected with the coupling unit of the connection device may be exposed to an outside through an opening formed in the side surface part such that the coupling unit of the connection device protrudes to the outside through the opening.

According to various embodiments, an area (e.g., the area 370), on which a portion of the connection device is seated, of the front surface part or the rear surface part may be recessed to be caved in toward an opposite surface from a surface facing the portable electronic device.

According to various embodiments, the protective case of the portable electronic device may further include a cover formed to cover an area, on which a portion of the connection device is seated, of the front surface part or the rear surface part.

According to various embodiments, the connection device may be formed integrally with the protective case of the portable electronic device.

According to various embodiments, a protective case (e.g., the protective case 300) of a portable electronic device, which includes a connection device (e.g., the USIM extension connection device 100) which is able to couple to the portable electronic device (e.g., the portable electronic device 200) may include a front surface part (e.g., the front surface part 310) formed to cover a front surface of the portable electronic device, a side surface part (e.g., the side surface part 330) formed to cover a side surface of the portable electronic device, a rear surface part (e.g., the rear surface part 350) formed to cover a rear surface of the portable electronic device, and a display device (e.g., the display device 390) formed in at least a portion of the front surface part, the side surface part, or the rear surface part. A coupling unit of the connection device coupled to a universal subscriber identity module (USIM) connector (e.g., the USIM connector 211) of the portable electronic device may be positioned at the side surface part. A circuit board (e.g., the FPCB 101) extending from the coupling unit and connected with a connector (e.g., the first connector 171) of the connection device, and the connector may be seated on at least a portion of the front surface part or the rear surface part. The display device may be electrically connected with the circuit board.

According to various embodiments, the circuit board of the connection device may be disposed inside at least a portion of the front surface part or the rear surface part. One end of the circuit board connected with the coupling unit of the connection device may be exposed to an outside through an opening formed in the side surface part such that the coupling unit of the connection device protrudes to the outside through the opening.

According to various embodiments, an area (e.g., the area 370), on which a portion of the connection device is seated, of the front surface part or the rear surface part may be recessed to be caved in toward an opposite surface from a surface facing the portable electronic device.

According to various embodiments, the protective case of the portable electronic device may further include a cover formed to cover an area, on which a portion of the connection device is seated, of the front surface part or the rear surface part.

According to various embodiments, the protective case of the portable electronic device may further include a processor (e.g., the processor 130) implemented on the circuit board. The processor may be configured to supply power to an external device connected with the connector of the connection device, to transceive data with the external device, or to control the display device.

According to various embodiments, the protective case of the portable electronic device may further include a switching circuit unit (e.g., the switching circuit unit 150) implemented on the circuit board, and at least one of a different connector (e.g., the second connector 173) connected with the circuit board. The processor may be configured to supply power to an external device selected from at least one external device, which is connected with the connector or the at least one of the different connector, through the switching circuit unit, or to transceive data with the selected external device.

The term “module” used in the present disclosure may represent, for example, a unit including one or more combinations of hardware, software and firmware. The term “module” may be interchangeably used with the terms “unit”, “logic”, “logical block”, “part” and “circuit”. The “module” may be a minimum unit of an integrated part or may be a part thereof. The “module” may be a minimum unit for performing one or more functions or a part thereof. The “module” may be implemented mechanically or electronically. For example, the “module” may include at least one of an application-specific IC (ASIC) chip, a field-programmable gate array (FPGA), and a programmable-logic device for performing some operations, which are known or will be developed.

At least a part of an apparatus (e.g., modules or functions thereof) or a method (e.g., operations) according to various embodiments may be, for example, implemented by instructions stored in a computer-readable storage media in the form of a program module. The instruction, when executed by a processor (e.g., the processor 620), may cause the one or more processors to perform a function corresponding to the instruction. The computer-readable storage media, for example, may be the memory 630.

A computer-readable recording medium may include a hard disk, a floppy disk, a magnetic media (e.g., a magnetic tape), an optical media (e.g., a compact disc read only memory (CD-ROM) and a digital versatile disc (DVD), a magneto-optical media (e.g., a floptical disk)), and hardware devices (e.g., a read only memory (ROM), a random access memory (RAM), or a flash memory). Also, the one or more instructions may contain a code made by a compiler or a code executable by an interpreter. The above hardware unit may be configured to operate via one or more software modules for performing an operation according to various embodiments, and vice versa.

A module or a program module according to various embodiments may include at least one of the above components, or a part of the above components may be omitted, or additional other components may be further included. Operations performed by a module, a program module, or other components according to various embodiments may be executed sequentially, in parallel, repeatedly, or in a heuristic method. In addition, some operations may be executed in different sequences or may be omitted. Alternatively, other operations may be added.

In addition, the embodiments disclosed in the present disclosure are suggested for the purpose of describing or understanding the disclosed technical content, but are not limited to the scope of the present invention. Accordingly, it will be understood by those skilled in the art that various changes in form and details may be made therein without departing from the spirit and scope of the present invention as defined by the appended claims and their equivalents.

1. An electronic device that is able to couple to a portable electronic device, the electronic device comprising:
a coupling unit coupled to a universal subscriber identity module (USIM) connector of the portable electronic device;
a circuit board extending from the coupling unit and connected with a plurality of connectors;
a processor implemented on the circuit board; and
a switching circuit unit,
wherein the processor is configured to:
supply power to an external device selected from at least one external device, which is connected with the plurality of connectors, through the switching circuit unit; or
transceive data with the selected external device.

2. The electronic device of claim 1, wherein the circuit board includes a flexible printed circuit board (FPCB).

3. The electronic device of claim 1, wherein the plurality of connectors include at least one of a USIM connector, an external memory connector, or an external power source connector.

4. A protective case of a portable electronic device, from which a connection device is detachable, the protective case comprising:
a front surface part formed to cover a front surface of the portable electronic device;
a side surface part formed to cover a side surface of the portable electronic device; and
a rear surface part formed to cover a rear surface of the portable electronic device,
wherein a coupling unit of the connection device coupled to a universal subscriber identity module (USIM) connector of the portable electronic device is positioned at the side surface part, and
wherein a circuit board extending from the coupling unit and connected with a plurality of connectors of the connection device, a processor implemented on the circuit board, a switching circuit unit implemented on the circuit board, and the plurality of connectors are seated on at least a portion of the front surface part or the rear surface part.

5. The protective case of claim 4, wherein at least a portion of the circuit board, the processor, or the switching circuit unit of the connection device is disposed inside the at least a portion of the front surface part or the rear surface part.

6. The protective case of claim 5, wherein, when the circuit board is disposed inside the at least a portion of the front surface part or the rear surface part, one end of the circuit board connected with the coupling unit of the connection device is exposed to an outside through an opening formed in the side surface part such that the coupling unit of the connection device protrudes to the outside through the opening.

7. The protective case of claim 4, wherein an area, on which a portion of the connection device is seated, of the front surface part or the rear surface part is recessed to be caved in toward an opposite surface from a surface facing the portable electronic device.

8. The protective case of claim 4, further comprising:
a cover formed to cover an area, on which a portion of the connection device is seated, of the front surface part or the rear surface part.

9. The protective case of claim 4, wherein the connection device is formed integrally with the protective case of the portable electronic device.

10. A protective case of a portable electronic device, which includes a connection device which is able to couple to the portable electronic device, the protective case comprising:
a front surface part formed to cover a front surface of the portable electronic device;
a side surface part formed to cover a side surface of the portable electronic device;
a rear surface part formed to cover a rear surface of the portable electronic device; and
a display device formed in at least a portion of the front surface part, the side surface part, or the rear surface part,
wherein a coupling unit of the connection device coupled to a universal subscriber identity module (USIM) connector of the portable electronic device is positioned at the side surface part,
wherein a circuit board extending from the coupling unit and connected with a connector of the connection device, and the connector are seated on at least a portion of the front surface part or the rear surface part, and
wherein the display device is electrically connected with the circuit board.

11. The protective case of claim 10, wherein the circuit board of the connection device is disposed inside the at least a portion of the front surface part or the rear surface part, and
wherein one end of the circuit board connected with the coupling unit of the connection device is exposed to an outside through an opening formed in the side surface part such that the coupling unit of the connection device protrudes to the outside through the opening.

12. The protective case of claim 10, wherein an area, on which a portion of the connection device is seated, of the front surface part or the rear surface part is recessed to be caved in toward an opposite surface from a surface facing the portable electronic device.

13. The protective case of claim 10, further comprising:
a cover formed to cover an area, on which a portion of the connection device is seated, of the front surface part or the rear surface part.

14. The protective case of claim 10, further comprising:
a processor implemented on the circuit board,
wherein the processor is configured to:
supply power to an external device connected with the connector of the connection device;
transceive data with the external device; or
control the display device.

15. The protective case of claim 14, further comprising:
a switching circuit unit implemented on the circuit board; and
at least one of a different connector connected with the circuit board,
wherein the processor is configured to:
supply power to an external device selected from at least one external device, which is connected with the connector or the at least one of the different connector, through the switching circuit unit; or
transceive data with the selected external device.
